(19) United States
(12) Patent Application Publication
(10) Pub. No.: US 2023/0101293 A1
(43) Pub. Date: Mar. 30, 2023

(54) Semiconductor Device and Method for Manufacturing the Same

(71) Applicant: Nippon Telegraph and Telephone Corporation, Tokyo (JP)

(72) Inventors: Masanobu Hiroki, Tokyo (JP); Kazuhide Kumakura, Tokyo (JP)

(21) Appl. No.: 17/908,493

(22) PCT Filed: Mar. 17, 2020
(86) PCT No.: PCT/JP2020/011700

§ 371 Date: Aug. 31, 2022

(51) Int. Cl. H01L 29/66; H01L 29/20; H01L 29/778

(52) U.S. Cl. CPC H01L 29/66462; H01L 29/2003; H01L 29/7786

(57) ABSTRACT

A buffer layer formed on a substrate, a base layer formed on the buffer layer, and a channel layer formed on the base layer are provided. The base layer includes AlₓGa₁₋ₓN(0<x≤1) and the composition x of Al decreases in accordance with increasing approach of the composition x to the channel layer in a thickness direction. The channel layer includes Al_{y}Ga_{1-y}N(0<y≤1) and the composition y of Al decreases in accordance with increasing approach of the composition y to the base layer in a thickness direction.

### CROSS-REFERENCE TO RELATED APPLICATIONS

This patent application is a national phase filing under section 371 of PCT application no. PCT/JP2020/011700, filed on Mar. 17, 2020, which application is hereby incorporated herein by reference in its entirety.

### TECHNICAL FIELD

The present invention relates to a semiconductor apparatus utilizing a nitride semiconductor and a method for producing the apparatus.

### BACKGROUND

Wide-gap semiconductors, such as GaN and SiC, are expected as materials for power devices. These wide-gap semiconductors have a higher dielectric breakdown field than that of Si. Therefore, utilizing wide-gap semiconductors makes it possible to produce low on-resistance and high withstand voltage semiconductor elements. There is a possibility that bandgaps, such as AlN and diamond, can further enhance the performance of power devices by utilizing a 5-6 eV ultra wide-bandgap (UWBG) semiconductor. The dielectric breakdown field of the UWBG semiconductor is 10˜12 MV/cm, which is higher than that of GaN or SiC. Therefore, AlN or diamond has the figure of merit that is ten times as high as that of GaN or SiC.

There is, however, a significant challenge in utilizing the UWBG semiconductor for power devices. The most significant challenge is the difficulty to lower the channel resistance. The UWBG semiconductor shows a large amount of ionization energy of the donor and the acceptor and a very low free carrier concentration at room temperature. For example, AlN shows that the ionization energy of the Si donor ranges 250-280 meV, and that even if AlN is doped with about 10¹⁸ cm⁻³ of Si, free electron concentration thereof remains approximately 10¹⁵ cm⁻³ at room temperature. Therefore, the resistivity of the channel including AlN is as high as about several tens of Ωcm. Furthermore, AlN shows a limitation such that in case of a high doping concentration, AlN contrarily reduces carrier concentration thereof due to a self-compensation effect.

Meanwhile, in the nitride semiconductor element, FET (PolFET: Polarization-doped FET), which utilizes polarization dope in an AlGaN layer which is compositionally graded in the thickness direction, is disclosed (NPL 1). This technique is demonstrated also in the wide-gap semiconductor (NPL 2). Because by utilizing this polarization dope a highly concentrated free carrier can be generated in a channel without doping of donor, it is possible for the UWBG semiconductor to lower channel resistance thereof.

NPL 2 describes a structure in which an AlN buffer layer and an Al_{0.6}Ga_{0.4} base layer having the thickness of 0.25 μm are formed on a substrate, and on the base layer, a compositionally graded channel layer having an Al composition changing from 0.6 to 1 and the thickness of 75 nm lies. In this structure, however, a negative difference in a polarization charge is generated at the interface between the AlN buffer layer and the Al_{0.6}Ga_{0.4}N base layer, and two-dimensional hole gas is generated due to valence band discontinuity. Therefore, there is a possibility that an effective carrier concentration is reduced.

If the AlGaN base layer is directly formed on the substrate and the above-mentioned compositionally graded channel layer is formed on the base layer, it is possible to suppress the generation of the two-dimensional hole gas. It is difficult, however, to grow the AlGaN base layer directory on the substrate and it is highly possible that the crystal defect density would be higher than that of the AlN buffer layer. Furthermore, since the AlGaN base layer has a lower dielectric breakdown field than that of the AlN layer, the improvement of the withstand voltage, which is an advantage of the utilization of the UWBG semiconductor, is limited.

### CITATION LIST

### Non Patent Literature

[NPL 1] S. Rajan et al., “AlGaN/GaN polarization-doped field-effect transistor for microwave power applications”, Applied Physics Letters, vol. 84, no. 9, pp. 1591-1593, 2004.
[NPL 2] A. M. Armstrong et al., “AlGaN polarization-doped field effect transistor with compositionally graded channel from Al_{0.6}Ga_{0.4}N to AlN”, Applied Physics Letters, vol. 114, 052103, 2019.

### SUMMARY

### Technical Problem

As previously mentioned, the above-mentioned FET structure which utilizes polarization dope in compositionally graded AlGaN shows promise in lowering the resistance of the UWBG semiconductor channel. The structure of NPL 2, however, has the problem of the generation of the two-dimensional hole gas, therefore, there is the possibility that an effective carrier concentration is reduced.

Embodiments of the present invention can solve the above problem, and an embodiment of the invention is to lower the resistance of the channel which utilizes the ultra wide-bandgap semiconductor.

### Means for Solving the Problem

The semiconductor apparatus according to embodiments of the present invention includes a buffer layer which is formed on a substrate and includes a nitride semiconductor including Al, a base layer which is formed on the buffer layer and includes AlₓGa₁₋ₓN(0<x≤1), a channel layer which is formed on the base layer and includes Al_{y}Ga_{1-y}N(0<y≤1), a source electrode and a drain electrode which are formed on the channel layer, and a gate electrode which is formed between the source electrode and the drain electrode on the channel layer. The base layer is made such that the composition x of Al decreases in accordance with an increasing approach of the composition x to the channel layer in a thickness direction, the channel layer is made such that the composition y of Al decreases in accordance with an increasing approach of the composition y to the base layer in a thickness direction, and the base layer and the channel layer are made such that both composition ratios of Al are the same at an interface between the base layer and the channel layer.

Additionally, a method for producing a semiconductor apparatus according to embodiments of the present invention includes a first step of forming, on a substrate, a buffer layer including AlN, a base layer including AlₓGa₁₋ₓN(0<x≤1), and a channel layer including Al_{y}Ga_{1-y}N(0<y≤1) on the base layer in this order; a second step of forming a source electrode and a drain electrode on the channel layer; and a third step of forming a gate electrode on the channel layer, the gate electrode being formed between the source electrode and the drain electrode. The base layer is made such that the composition x of Al decreases in accordance with an increasing approach of the composition x to the channel layer in a thickness direction, the channel layer is made such that the composition y of Al decreases in accordance with an increasing approach of the composition y to the base layer in the thickness direction, and the base layer and the channel layer are made such that both composition ratios of Al are the same at an interface between the base layer and the channel layer.

### Effects of Embodiments of the Invention

As explained above, according to embodiments of the present invention, since the base layer including AlₓGa₁₋ₓN is made such that the composition x of Al decreases in accordance with an increasing approach of the composition x to the channel layer in a thickness direction and the channel layer which is formed on the base layer and includes Al_{y}Ga_{1-y}N is made such that the composition y of Al decreases in accordance with an increasing approach of the composition y to the base layer in the thickness direction, the lowering of the resistance of the channel which utilizes the ultra wide-bandgap semiconductor can be achieved.

### BRIEF DESCRIPTION OF THE DRAWINGS

FIG. 1 is a cross sectional view showing the configuration of the semiconductor apparatus in accordance with an embodiment of the present invention.

FIG. 2 is a cross sectional view showing the configuration of another semiconductor apparatus in accordance with an embodiment of the present invention.

FIG. 3A is a characteristic diagram showing a band diagram and a carrier concentration profile in each layer of the semiconductor apparatus in accordance with an embodiment.

FIG. 3B is a characteristic diagram showing a band diagram and a carrier concentration profile in each layer of the semiconductor apparatus in accordance with an embodiment.

FIG. 3C is a characteristic diagram showing a band diagram and a carrier concentration profile in each layer of the semiconductor apparatus in accordance with an embodiment.

FIG. 3D is a characteristic diagram showing a band diagram and a carrier concentration profile in each layer of the semiconductor apparatus in accordance with an embodiment.

FIG. 3E is a characteristic diagram showing a band diagram and a carrier concentration profile in each layer of the semiconductor apparatus in accordance with an embodiment.

FIG. 4 is a characteristic diagram showing the relationship between a three-dimensional polarization charge concentration generated in a base layer and the layer thickness of the base layer.

FIG. 5A is a characteristic diagram showing the relationship between the effective electron concentration (electron concentration-hole concentration) of the semiconductor apparatus in accordance with the embodiment described using FIG. 3B and the concentration of Si doping to the base layer.

FIG. 5B is a characteristic diagram showing the band diagram and the carrier concentration profile of the structure in which an AlGaN layer with an Al composition 0.8 is disposed in place of the base layer.

FIG. 6 is a characteristic diagram showing the Al composition dependence of the critical layer thickness of an AlGaN layer on an AlN layer.

FIG. 7 is a characteristic diagram showing the changes of the sheet carrier concentration when the thickness of a barrier layer of the semiconductor apparatus in accordance with the embodiment described using FIG. 3C changes.

FIG. 8A is a cross sectional view showing the configuration of another semiconductor apparatus in accordance with an embodiment of the present invention.

FIG. 8B is a cross sectional view showing the configuration of another semiconductor apparatus in accordance with an embodiment of the present invention.

FIG. 8C is a cross sectional view showing the configuration of another semiconductor apparatus in accordance with an embodiment of the present invention.

FIG. 8D is a cross sectional view showing the configuration of another semiconductor apparatus in accordance with an embodiment of the present invention.

FIG. 8E is a characteristic diagram showing simulation results of the relationship between the depth of a recess and the plot voltage of the semiconductor apparatus in accordance with the embodiment described using FIG. 8D.

FIG. 8F is a cross sectional view showing the configuration of another semiconductor apparatus in accordance with an embodiment of the present invention.

FIG. 9A is a cross sectional view showing the configuration of the semiconductor apparatus in the production process to describe a method for producing the semiconductor apparatus in accordance with an embodiment of the present invention.

FIG. 9B is a cross sectional view showing the configuration of the semiconductor apparatus in the production process to describe a method for producing the semiconductor apparatus in accordance with an embodiment of the present invention.

FIG. 9C is a cross sectional view showing the configuration of the semiconductor apparatus in the production process to describe a method for producing the semiconductor apparatus in accordance with an embodiment of the present invention.

FIG. 10A is a cross sectional view showing the configuration of the semiconductor apparatus in the production process to describe a method for producing the semiconductor apparatus in accordance with an embodiment of the present invention.

FIG. 10B is a cross sectional view showing the configuration of the semiconductor apparatus in the production process to describe a method for producing the semiconductor apparatus in accordance with an embodiment of the present invention.

FIG. 10C is a cross sectional view showing the configuration of the semiconductor apparatus in the production process to describe a method for producing the semiconductor apparatus in accordance with an embodiment of the present invention.

FIG. 11A is a cross sectional view showing the configuration of the semiconductor apparatus in the production process to describe a method for producing the semiconductor apparatus in accordance with an embodiment of the present invention.

FIG. 11B is a cross sectional view showing the configuration of the semiconductor apparatus in the production process to describe a method for producing the semiconductor apparatus in accordance with an embodiment of the present invention.

FIG. 11C is a cross sectional view showing the configuration of the semiconductor apparatus in the production process to describe a method for producing the semiconductor apparatus in accordance with an embodiment of the present invention.

### DETAILED DESCRIPTION OF ILLUSTRATIVE EMBODIMENTS

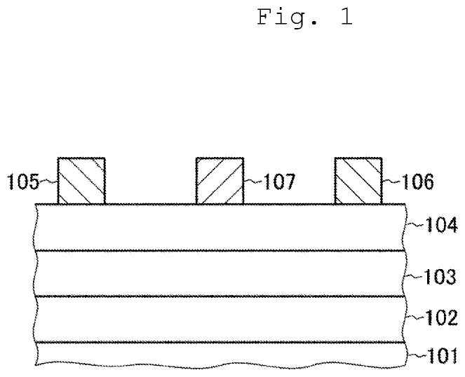

The semiconductor apparatus in accordance with an embodiment of the present invention is described below with reference to FIG. 1. This semiconductor apparatus comprises a buffer layer 102 formed on a substrate 101, a base layer 103 formed on the buffer layer 102, and a channel layer 104 formed on the base layer 103. Furthermore, this semiconductor apparatus also comprises a source electrode 105 and a drain electrode 106 which are formed on the channel layer 104, and a gate electrode 107 formed between the source electrode 105 and the drain electrode 106 on the channel layer 104. This semiconductor apparatus is a field effect transistor.

The substrate 101 can be, for example, a sapphire substrate with the main surface of C face, a single crystal Si substrate, a single crystal SiC substrate, a GaN substrate, or an AlN substrate. The buffer layer 102 includes a nitride semiconductor including Al such as AlN.

The base layer 103 includes AlₓGa₁₋ₓN(0<x≤1). For example, the base layer 103 includes AlₓGa₁₋ₓN(0.7<x≤1). Furthermore, the base layer 103 is made such that the composition x of Al decreases in accordance with an increasing approach of the composition x to the channel layer 104 in the thickness direction. Moreover, the base layer 103 can also have a configuration doped with Si. Herein, the buffer layer 102 can include AlₓGa₁₋ₓN which is the same composition as the base layer 103 the buffer layer 102 is in contact with.

The channel layer 104 includes Al_{y}Ga_{1-y}N(0<y≤1). For example, the channel layer 104 includes Al_{y}Ga_{1-y}N(0.7<y≤1). Furthermore, the channel layer 104 is made such that the composition y of Al decreases in accordance with an increasing approach of the composition y to the base layer 103 in the thickness direction.

Moreover, the base layer 103 and the channel layer 104 are made such that both composition ratios of Al are the same at the interface between the base layer 103 and the channel layer 104. As will be described later, the layer thickness and composition of the base layer 103 affect electrons in the channel layer 104. Also, as will be described later, the layer thickness and composition of the channel layer 104 affect electrons in the channel layer 104.

The source electrode 105 and the drain electrode 106 are in ohmic-contact with the channel layer 104. Furthermore, the gate electrode 107, for example, is Schottky-junctioned to the channel layer 104. Moreover, the gate electrode 107 can also be provided on the channel layer 104 through a gate insulating layer (not shown).

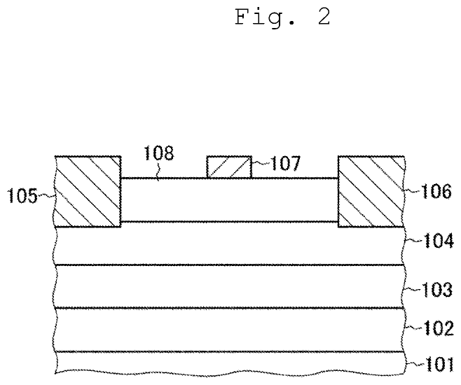

Additionally, as shown in FIG. 2, this semiconductor apparatus can also have a configuration provided with a barrier layer 108 which is formed on the channel layer 104 and includes a nitride semiconductor including Al. In this case, the barrier layer 108 is formed between the source electrode 105 and the drain electrode 106, and the gate electrode 107 is formed on the barrier layer 108. Furthermore, the source electrode 105 and the drain electrode 106, for example, can also be formed on the thin part of the channel layer 104. Also, in case that the barrier layer 108 is provided, it is important that the source electrode 105 and the drain electrode 106 are made to be in ohmic-contact with the channel layer 104. Moreover, in order to lower the contact resistance, impurity regions can also be created in regions of the channel layer 104 under the source electrode 105 and the drain electrode 106 by ion implantation of Si, Ge and the like.

The barrier layer 108, for example, can include AlN. In addition, the barrier layer 108 can also include AlGaN which has a high Al composition, which is an Al composition ranging from about 0.7 to 1. As will be described later, the barrier layer 108 affects an electron concentration and electron confinement in the channel layer 104. Furthermore, the barrier layer 108 can also have a configuration doped with Si.

As the doping concentration in the barrier layer 108 increases, the free electron concentration in the channel layer 104 rises. This effect can be equally obtained even if the base layer 103 is not doped with Si. Although the doping concentration of the barrier layer 108 is adjusted according to uses, the upper limit is to be set equal to or less than a concentration which generates a self-compensation effect. For example, when the barrier layer 108 includes AlGaN which has a high Al composition, which is an Al composition ranging from about 0.7 to 1, the Si concentration as a dopant is to be set to have an upper limit of 1×10¹⁹ cm⁻³ or less which does not generate a self-compensation effect.

Next, the impact of the base layer 103 on the electrons in the channel layer 104 is described.

In an AlGaN layer (compositionally graded layer) in which the composition of Al is graded, as is mentioned in reference literature 1, a three-dimensional-like polarized charge is generated. Assuming that a composition difference of a compositionally graded layer is Δx and a layer thickness is d, polarization charge density (volume charge density) can be expressed as approximately 5×10¹³×Δx/d. As for AlGaN which grew in a group III polarity direction (+c-axis direction), in compositionally graded AlGaN in which an Al composition decreases with the growth, a negative polarization charge is generated in a +c-axis direction. Meanwhile, as for AlGaN which grew in a group III polarity direction, in compositionally graded AlGaN in which an Al composition rises with the growth, a positive polarization charge is generated in a +c-axis direction.

Therefore, in the base layer 103, a negative polarization charge is generated toward the channel layer 104, and, in the channel layer 104, a positive polarization charge is generated toward the side of the gate electrode 107. Because of the effects of these polarization charges, free electrons are induced in the channel layer 104, while free holes are generated (induced) in the base layer 103. The polarization charge density in these layers, as previously mentioned, depends on the degree of a composition gradient (Δx/d). When the degrees of the composition gradients of the channel layer 104 and the base layer 103 are the same, electrons and holes both of which have almost the same degree of the concentrations must be generated in each layer.

In embodiments of the present invention, in order to suppress free holes in the base layer 103, first of all, for example, the base layer 103 is doped with donor (such as Si) for the purpose of compensating a negative polarization charge. Additionally, doping the barrier layer 108 with donor makes it possible to improve the electron concentration of the channel layer 104. Second, such a technique is employed that the degree of the composition changes of a base layer is made to be gentler than that of a channel layer. By making the degree of the composition changes gentle, polarization charge density can be decreased. Decreasing polarization charge density makes it possible that the donor concentration with which the base layer 103 is doped is reduced.

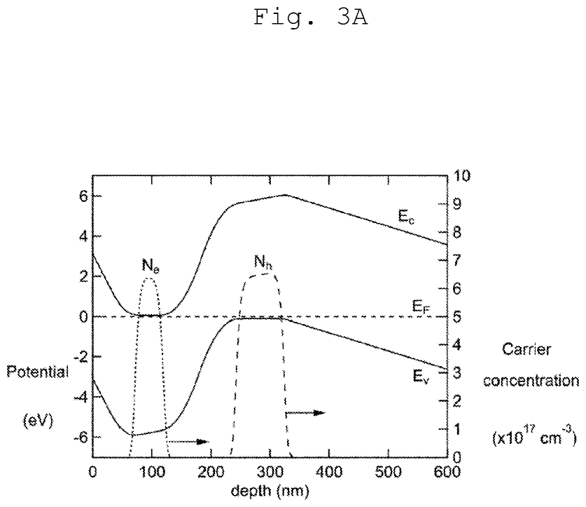

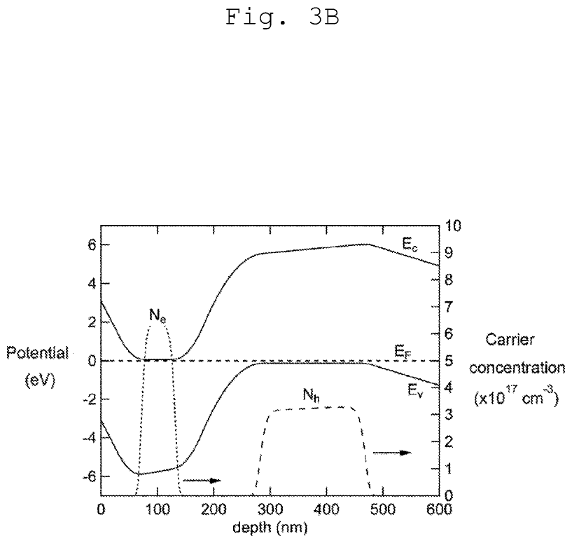

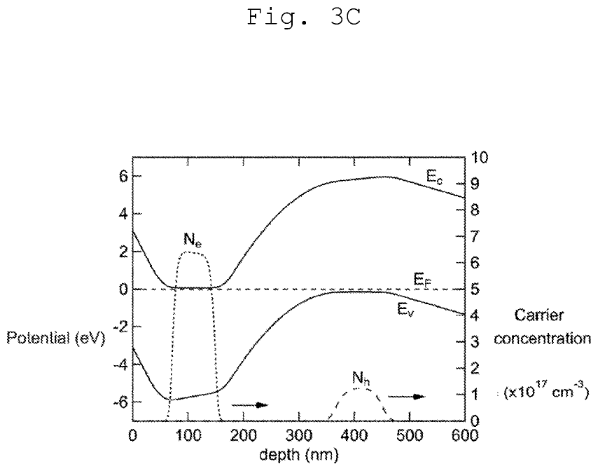

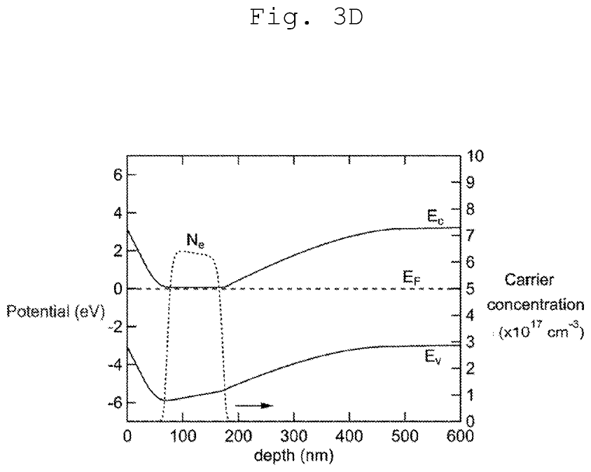

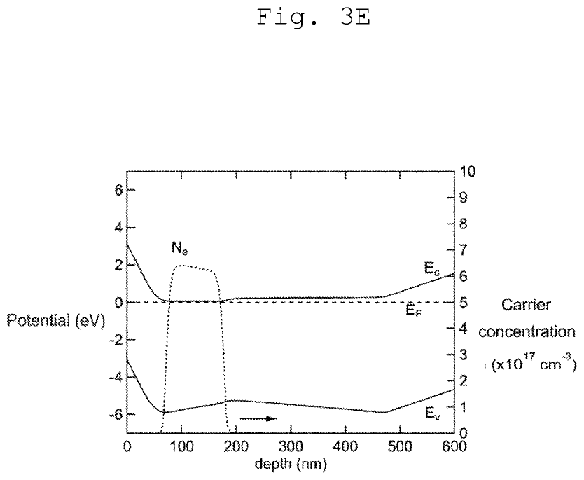

As an example, FIG. 3A shows a band diagram and a carrier concentration profile (a dotted line Nₑ, a broken line Nₕ), which are found by Poisson's equation, of a layer structure in which the base layer 103 with the layer thickness of 150 nm and the Al composition decreasing from 1 to 0.8 is formed on the buffer layer 102, the channel layer 104 with the layer thickness of 150 nm and the Al composition increasing from 0.8 to 1 is formed on the base layer 103, and the barrier layer 108 with the layer thickness of 30 nm is formed on the channel layer 104. The holes (Nₕ) have almost the same degree of the concentrations as that of electrons (Nₐ) of the channel layer 104.

As an additional example, FIG. 3B shows a band diagram and a carrier concentration profile in the case that the layer thickness of the base layer 103 is set to be 300 nm. Since the composition gradient of the base layer 103 becomes gentle, the negative polarization charge decreases. Therefore, although the sheet concentration does not change from that shown in FIG. 3A, the maximum concentration of holes in the base layer 103 is reduced approximately by half.

FIG. 3C shows a band diagram and a carrier concentration profile in the case that the base layer 103 is doped with 2×10¹⁷ cm⁻³ of Si which is smaller than polarization charge density. Although holes are generated in the base layer, the concentration of the generated holes is reduced. FIG. 3D shows a band diagram and a carrier concentration profile in the case that the base layer 103 is doped with 3×10¹⁷ cm⁻³ of Si which is almost the same as polarization charge density. In this case, the generation of holes is suppressed. Even if the concentration is increased further, the generation of holes remains suppressed.

FIG. 3E shows a band diagram and a carrier concentration profile of the structure in which the base layer 103 with the structure described using FIG. 3B is doped with 1×10¹⁷ cm⁻³ of Si. As with the case of FIG. 3D, the generation of holes is suppressed. The conduction band of the base layer 103, however, presents flat state near Fermi energy. From the view point of buffer leakage suppression, the lifted state of the conduction band is preferred as shown in FIG. 3D.

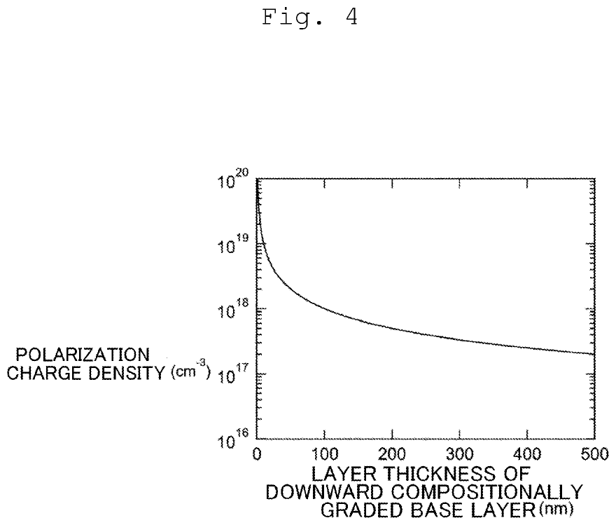

As explained above, by doping the base layer 103 with donor, the impact of the three-dimensional polarization charge in the base layer 103 can be mitigated and the generation of holes in the base layer 103 can be suppressed. Furthermore, the three-dimensional polarization charge density changes according to the degree of the composition gradient of the base layer 103. FIG. 4 shows the relationship between the three-dimensional polarization charge concentration generated in the base layer 103 and the layer thickness of the base layer 103 in which the Al composition decreases from 1 to 0.8. When the layer thickness of the base layer 103 is 300 nm, the polarization charge density is 3.3×10¹⁷ cm⁻³.

In embodiments of the present invention, when the doping concentration of donor with which the base layer 103 is doped is the concentration (1×10¹⁸ cm⁻³) or less which does not generate a self-compensation effect, the doping concentration is effective, but it is desired that the doping concentration is the concentration (polarization charge density±1×10¹⁷ cm⁻³) which is nearly equal to the polarization charge density of the base layer 103.

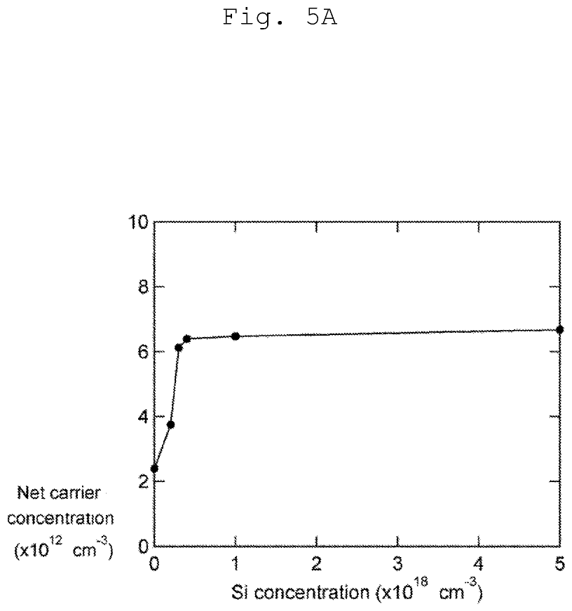

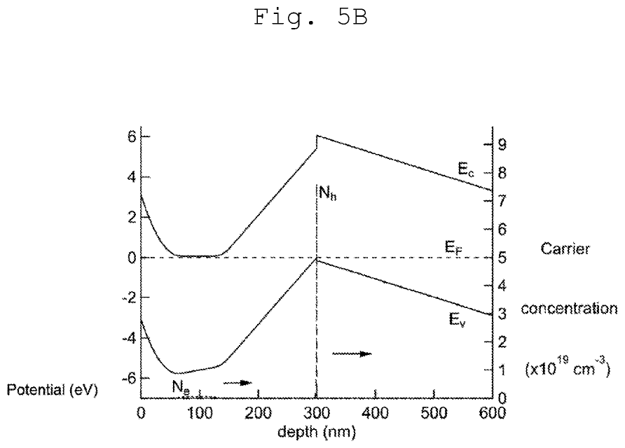

FIG. 5A shows the relationship between the effective electron concentration (electron concentration-hole concentration) of the structure in FIG. 3B and the doping concentration of Si with which the base layer 103 is doped. When the effective electron concentration is the polarization charge density or less, the concentration increases as the doping concentration increases, while the electron concentration does not change when the concentration is the polarization charge density or more. For reference, FIG. 5B shows a band diagram and a carrier concentration profile of the structure in which, like a prior art of PolFET, AlGaN layer with a 0.8 Al composition is disposed in place of the base layer 103. In this case, a highly concentrated two-dimensional hole gas (Nₕ) is generated at the interface between the Al_{0.8}Ga_{0.2}N layer and the AlN buffer layer.

Next, the impact of the layer thickness and composition of the channel layer 104 on the electrons in the channel layer 104 is described.

The impact of the layer thickness and composition of the channel layer 104 also affects the electric characteristic of the channel layer 104. As previously mentioned, the positive charge density in the channel layer 104 changes according to the degree of the composition gradient (change). When the degree of the gradient becomes steep, the positive polarization charge density increases. What degree of gradient to be decided is adjusted according to the uses of a nitride semiconductor device, but whatever degree of gradient is used, the effects of embodiments of the present invention are not affected.

Moreover, while doping the channel layer 104 with donor can make the free electron concentration increase, the doping causes the electron mobility to decrease. Doping or not doping the channel layer 104 with donor and the concentration depend on the uses of a device, whereas, if the concentration is equal to or less than the concentration which generates a self-compensation effect, the effects of embodiments of the present invention are not affected.

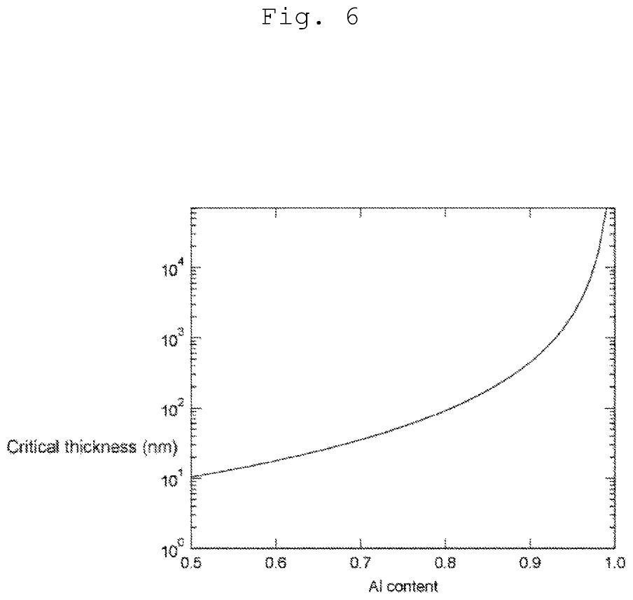

Next, the restriction on the layer thicknesses of the base layer 103 and the channel layer 104 is described. It is important that the total layer thickness of the base layer 103 and the channel layer 104 is equal to or less than the critical layer thickness which generates lattice relaxation. This critical layer thickness is nearly equal to that of an AlGaN layer having the same composition as the average composition of the base layer 103 and the channel layer 104. FIG. 6 shows the Al composition dependence of the critical layer thickness of the AlGaN layer lying on an AlN layer and the composition dependence is estimated by the formula of People and Bean (reference literature 2). If the total layer thickness of the base layer 103 and the channel layer 104 is equal to or less than the critical layer thickness corresponding to the AlGaN layer having the average composition of these layers, the effects of embodiments of the present invention are not affected.

Next, the impact (electron confinement) of the barrier layer 108 is described. Providing the barrier layer 108 having a bandgap which is the same as or bigger than that of the channel layer 104 can improve the free electron concentration in the channel layer 104. This is because the polarization charge of the barrier layer 108 and the electron confinement in the channel layer 104 improve. Without the barrier layer 108, the surface side of the channel layer 104 is depleted and free electrons cannot exist. Forming the barrier layer 108 makes electrons to be distributed in the entire channel layer 104. Furthermore, the polarization effect of the barrier layer 108 also contributes to the improvement of the free electron concentration of the channel layer 104.

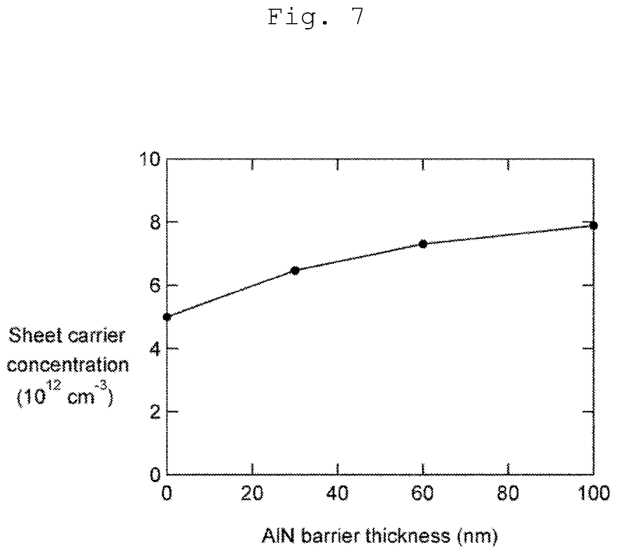

Moreover, forming the barrier layer 108 produces an effect of the suppression of gate leakage. The thicker the barrier layer becomes, the more effective the improvement of electron concentration and the like come to be. Herein, the change of the sheet carrier concentration is shown in FIG. 7, when the barrier layer 108 thickness changes in the structure having the base layer 103 and the channel layer 104 both of which have the same configuration as that of FIG. 3C. As the layer thickness of the barrier layer 108 increases, the sheet carrier concentration increases. Furthermore, the barrier layer 108 is effective in the suppression of gate leakage. Meanwhile, when the barrier layer 108 is thick, such a disadvantage appears that the mutual conductance of the transistor is lowered. By making the barrier layer 108's only portion immediately beneath the gate to be thin, a transistor with low mutual conductance and low sheet resistance can be produced.

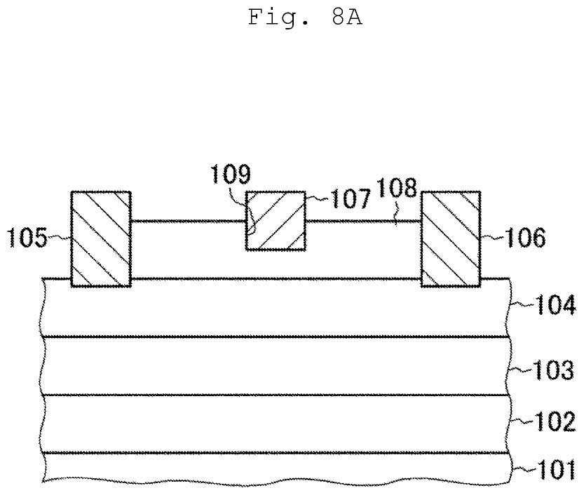

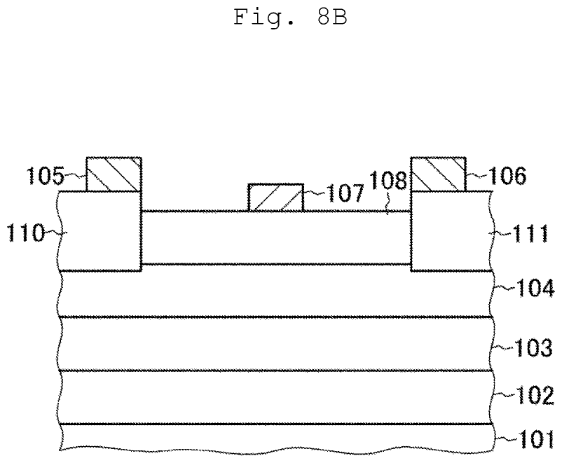

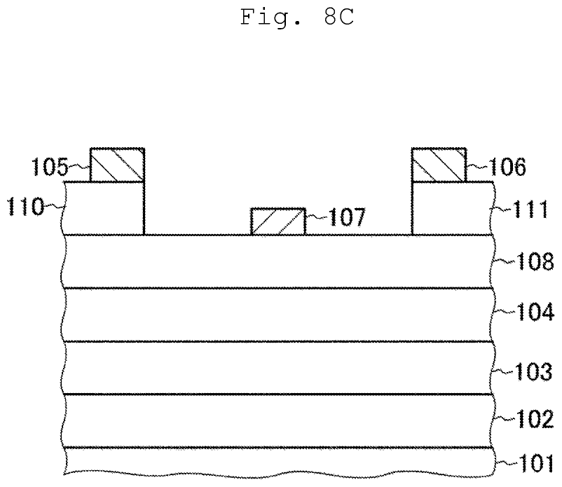

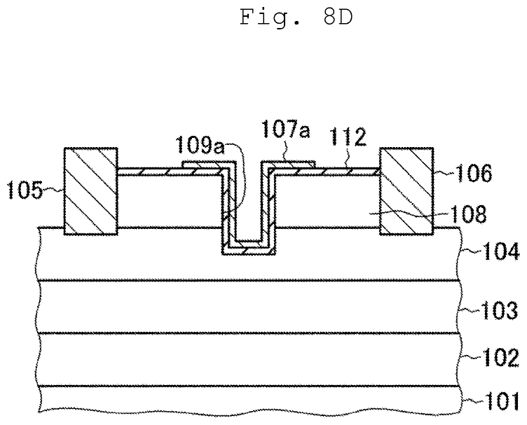

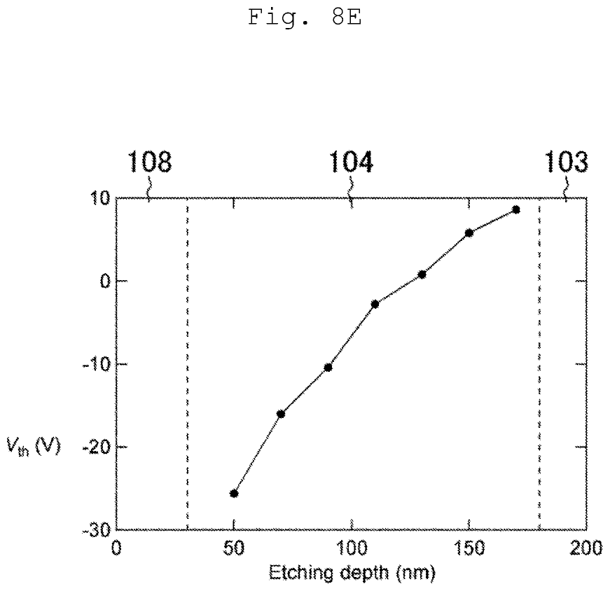

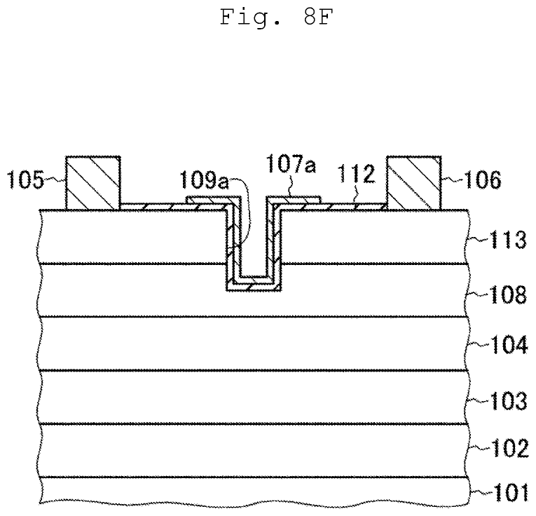

Next, another semiconductor apparatus (field effect transistor) in accordance with an embodiment of the present invention is described with reference to FIGS. 8A, 8B, 8C, 8D, 8E, and 8F.

For example, as shown in FIG. 8A, the barrier layer 108 is partially removed from the surface to make the layer thinner, a recess 109 is formed in the barrier layer 108, and the gate electrode 107 is provided in the recess 109. Other aspects of the configuration are the same as the transistor described using FIG. 2. By providing the gate electrode 107 in the recess 109, the threshold voltage can be adjusted. The depth of the recess 109 is adjusted according to the uses of the transistor.

Additionally, for example, as shown in FIG. 8B, the channel layer 104 is partially removed from the surface to make the layer thinner, and a first contact layer 110 and a second contact layer in can also be formed on these portions. The source electrode 105 is formed on the first contact layer 110 and the drain electrode 106 is formed on the second contact layer 111. The first contact layer 110 and the second contact layer in can be made to be compositionally graded AlGaN layers in which the composition of Al decreases from 1 to 0 in the direction away from the channel layer 104. Furthermore, the barrier layer 108 is formed between the source electrode 105 and the drain electrode 106 and the gate electrode 107 is formed on the barrier layer 108.

Moreover, as shown in FIG. 8B, it is also possible that on the barrier layer 108 on which the gate electrode 107 is formed, the first contact layer 110 and the second contact layer 11 are formed with the gate electrode 107 between them and furthermore the drain electrode 106 is formed on the second contact layer in.

One of the problems of the ultra wide-bandgap semiconductor is the difficulty to lower the contact resistance of the ohmic contact. This is because it is difficult to lower a barrier height with metal as the ultra wide-bandgap semiconductor has a small electron affinity.

To cope with this, in embodiments of the present invention, the first contact layer 110 and the second contact layer in are formed in the regions of the source electrode 105 and the drain electrode 106. The first contact layer 110 and the second contact layer in each have an Al composition of AlGaN which is made to decrease in accordance with an increasing approach of the Al compositions to the electrodes, and the outermost surfaces of the layers are made to be AlGaN with a low Al composition. Thereby, the electron affinity at the contact portions with the electrodes is enhanced to achieve the lowering of the electrical contact resistance with the electrodes.

Furthermore, in the first contact layer 110 and the second contact layer 111 which each have such a graded composition, as previously mentioned, the negative polarization charge is generated. To compensate this, the first contact layer 110 and the second contact layer in are doped with the donor impurities such as Si and Ge to the extent equal to or more than the polarization charge (5×10¹³×Δx/d) of the first contact layer 110 and the second contact layer 111.

Additionally, as shown in FIG. 8D, it is also possible that the recess 109a is formed in the barrier layer 108 and a part of the channel layer 104 in the thickness direction, and that the gate electrode 107a is formed through a gate insulating layer 112.

As previously mentioned, the negative polarization charge is generated in the base layer 103. By utilizing this negative polarization charge, an enhancement type field effect transistor can be produced. It is difficult to configure the enhancement type field effect transistor by a prior art of HEMT (High Electron Mobility Transistor) utilizing a heterojunction between an AlGaN layer and a GaN layer because of a two-dimensional electron gas induced at a heterointerface due to a polarization charge.

In HEMT utilizing a heterojunction between an AlGaN layer and a GaN layer, there is a recessed gate structure as one of the techniques to produce the enhancement type field effect transistor. By making the gate region of an AlGaN barrier layer thinner, the two-dimensional electron gas at the heterointerface is eliminated and an enhancement type operation is achieved. The threshold voltage becomes shallow as the depth of recess etching (etching elimination quantity) increases. In this technique, however, the control range of the threshold voltage is narrow.

Even the field effect transistor having the structure of embodiments of the present invention usually performs a depletion operation because free electrons are induced due to the polarization charge of the channel layer 104. To cope with this, the recess 109a is formed in the gate region, as mentioned above, and the gate electrode 107a is provided there, thereby, the enhancement type operation becomes possible. In addition, according to embodiments of the present invention, since the base layer 103 has a negative polarization charge, there is an advantage that the control range of the threshold voltage is wider than that of the recess structure of HEMT utilizing the heterojunction between the AlGaN layer and the GaN layer.

FIG. 8E shows the simulation results of the relationship between the depth of the recess 109a and the plot voltage in the field effect transistor having the above-mentioned structure of embodiments of the present invention. The simulation was performed, assuming that the thickness of the gate insulating layer 112 was 10 nm, the thickness of the barrier layer 108 was 30 nm, the thickness of the channel layer 104 was 150 nm, and the thickness of the base layer 103 was 300 nm. In addition, the simulation was performed, assuming that the donor concentration of the base layer 103 was 3×10¹⁷ cm⁻³. The depth of the recess 109a was assumed to range from 50 nm to 170 nm. The threshold voltage greatly changed from −25.6 V to +8.6 v. When the depth of the recess 109a is equal to 130 nm or more, a normally-off operation can be found. Furthermore, although the change of the threshold voltage with respect to the depth of the recess 109a is different according to the layer thickness and the composition of each layer, the effects of embodiments of the present invention are not affected.

Moreover, as shown in FIG. 8F, it is also possible that the contact layer 113 is formed on the barrier layer 108; the recess 109a is formed in the contact layer 113 and a part of the barrier layer 108 in the thickness direction; and the gate electrode 107a is formed through the gate insulating layer 112. The contact layer 113 is a compositionally graded AlGaN layer in which the composition of Al decreases from 1 to 0 in the direction away from the channel layer 104. The source electrode 105 and the drain electrode 106 are formed on the contact layer 113. Because of the contact layer 113, the electron affinity at the contact portions with the source electrode 105 and the drain electrode 106 becomes enhanced and the electrical contact resistance with the source electrode 105 and the drain electrode 106 is lowered.

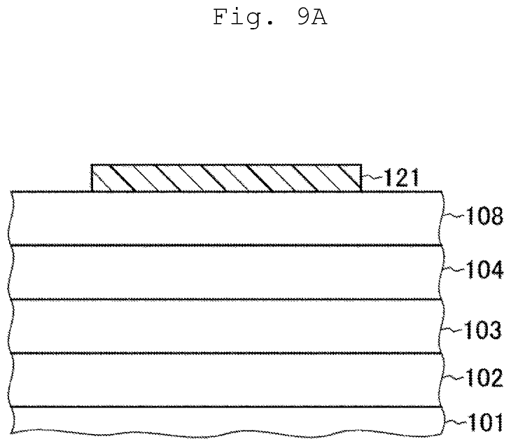

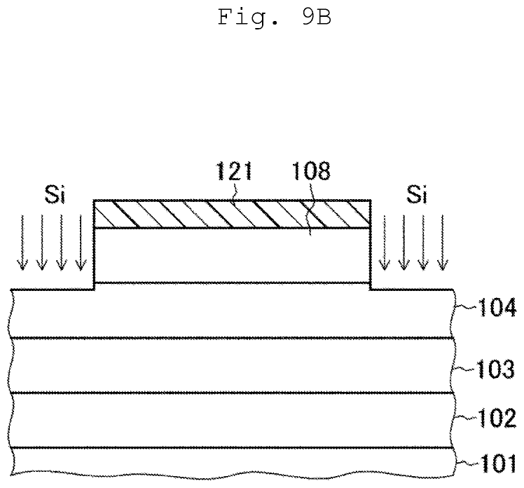

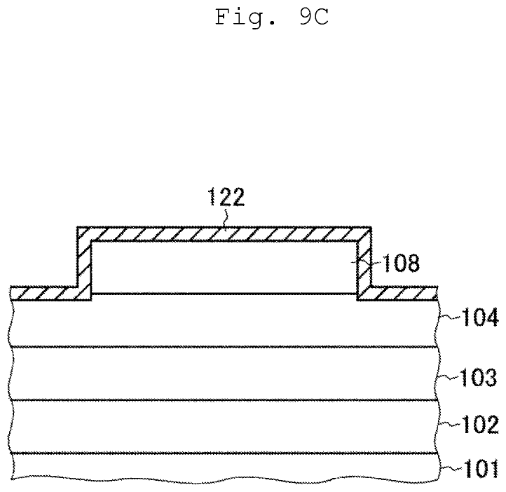

The method for producing the semiconductor apparatus in accordance with an embodiment of the present invention is described below. First, as shown in FIG. 9A, on the substrate 101, the buffer layer 102, the base layer 103, the channel layer 104, and the barrier layer 108 are formed (a first step). For example, each layer can be formed by known crystal growth technologies such as metalorganic chemical vapor deposition and molecular beam epitaxy.

Next, an insulating film is formed on the barrier layer 108 by, for example, depositing silicon oxide, and a mask pattern 121 is formed on the barrier layer 108 by patterning this insulating film by a known lithography technology and a known etching technology.

Next, as shown in FIG. 9B, the barrier layer 108 and the channel layer 104 are partially removed in the thickness direction by etching using the mask pattern 121 as a mask. Then, Si or Ge is implanted into the channel layer 104 exposed by etching in the form of selective ion implantation using the mask pattern 121 as a mask.

Next, after the mask pattern 121 is removed, as shown in FIG. 9C, an activation process is performed by covering the surfaces of the exposed barrier layer 108 and the exposed channel layer 104 with a protective film 122 including, for example, silicon oxide. After that, the source electrode 105 and the drain electrode 106 are formed by, for example, a well-known lift-off method and the like (a second step), and the gate electrode 107 is formed (a third step). By doing these, the semiconductor apparatus (field effect transistor) described using FIG. 2 can be obtained.

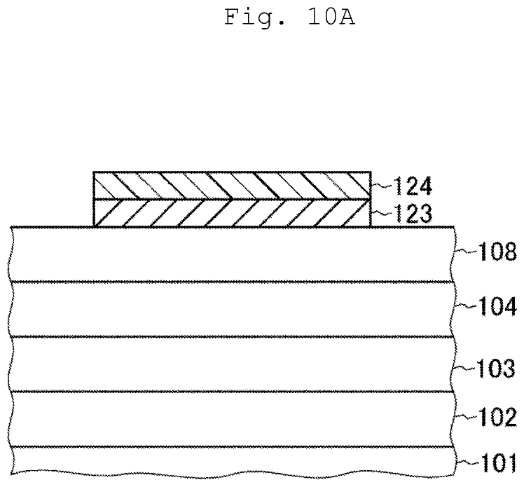

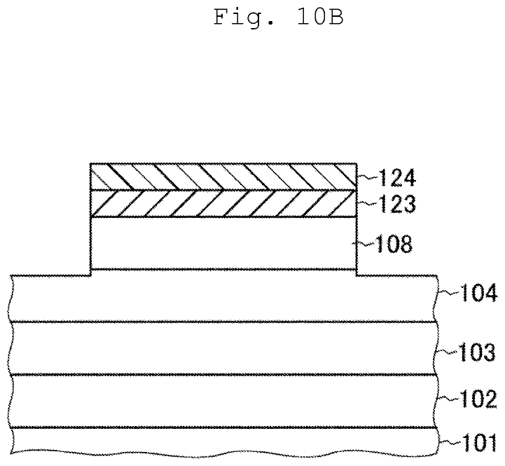

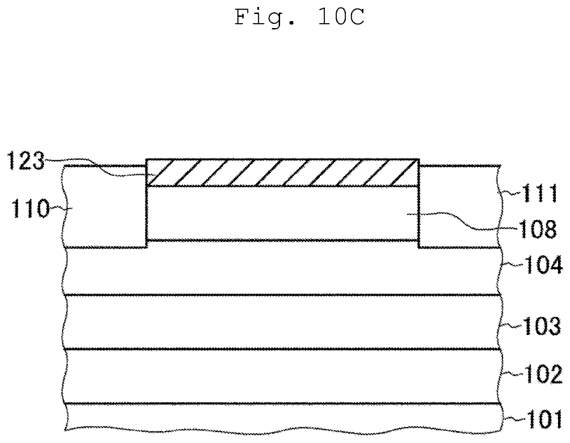

Next, a method for producing another semiconductor apparatus in accordance with an embodiment of the present invention is described. First, as shown in FIG. 10A, on the substrate 101, the buffer layer 102, the base layer 103, the channel layer 104, and the barrier layer 108 are formed (a first step). For example, each layer can be formed by known crystal growth technologies such as metalorganic chemical vapor deposition and molecular beam epitaxy.

Next, an insulating film is formed on the barrier layer 108 by, for example, depositing silicon oxide, a resist pattern 124 is formed on this insulating film by a known lithography technology, and an inorganic pattern 123 is formed on the barrier layer 108 by patterning the insulating film by a known etching technology utilizing this resist pattern 124.

Next, as shown in FIG. 10B, the barrier layer 108 and the channel layer 104 are partially removed in the thickness direction by etching using the resist pattern 124 (the inorganic pattern 123) as masks. Then, the resist pattern 124 is removed, and the first contact layer 110 and the second contact layer 11 are grown from the exposed channel layer 104 by a selection regrowth utilizing the inorganic pattern 123 (FIG. 10C).

After that, the inorganic pattern 123 is removed, the source electrode 105 and the drain electrode 106 are formed (a second step), and the gate electrode 107 is formed (a third step). Furthermore, it is also possible that a recess is formed in the barrier layer 108 and that the gate electrode 107 is formed there. Moreover, it is also possible that before the gate electrode 107 is formed, a gate insulating layer is formed and that the gate electrode is formed on the gate insulating layer.

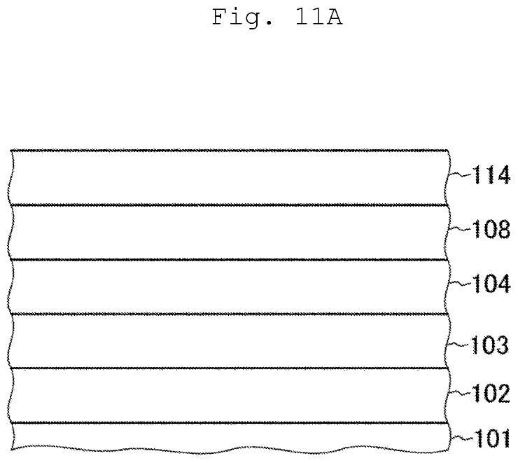

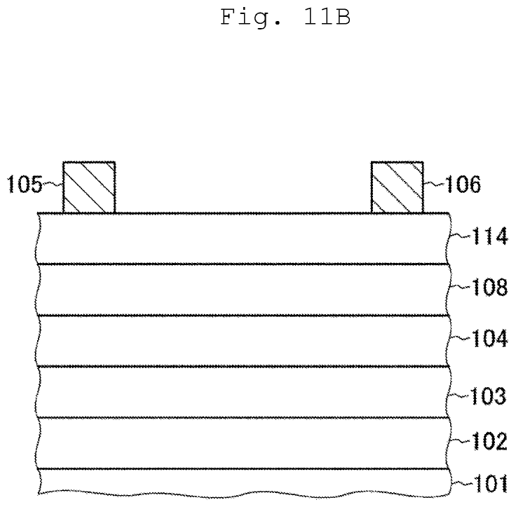

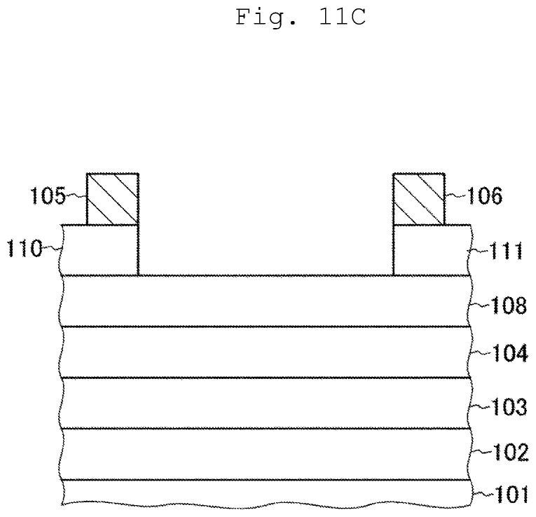

Next, a method for producing another semiconductor apparatus in accordance with an embodiment of the present invention is described. First, as shown in FIG. 11A, on the substrate 101, the buffer layer 102, the base layer 103, the channel layer 104, and the barrier layer 108 are formed (a first step). In this example, a compositionally graded AlGaN layer 114 is further formed on the barrier layer 108. In the compositionally graded AlGaN layer 114, the composition of Al decreases from 1 to 0 in the thickness direction. For example, each layer can be formed by known crystal growth technologies such as metalorganic chemical vapor deposition and molecular beam epitaxy.

Next, after the substrate 101 is taken out from the above-mentioned growth equipment utilized for the growth of each layer, as shown in FIG. 11B, the source electrode 105 and the drain electrode 106 are formed at a predetermined distance on the compositionally graded AlGaN layer 114 (a second step).

Next, as shown in FIG. 11C, the first contact layer 110 and the second contact layer 111 are formed by patterning the compositionally graded AlGaN layer 114 by the known lithography technology and the known etching technology. After that, the gate electrode 107 is formed on the barrier layer 108 (a third step). By doing these, the transistor described using FIG. 8C can be obtained. Moreover, it is also possible that a recess is formed in the barrier layer 108 and that the gate electrode 107 is formed there.

As explained above, according to embodiments of the present invention, since the base layer including AlₓGa₁₋ₓN(0<x≤1) is made such that the composition x of Al decreases in accordance with an increasing approach of the composition x to the channel layer in the thickness direction and the channel layer which is formed on the base layer and includes Al_{y}Ga_{1-y}N(0<y≤1) is made such that the composition y of Al decreases in accordance with an increasing approach of the composition y to the base layer in the thickness direction, the lowering of the resistance of the channel which utilizes the ultra wide-bandgap semiconductor can be achieved.

Furthermore, embodiments of the present invention should not be limited to the above-mentioned embodiments and it will be apparent that many modifications and combinations can be made by a person ordinarily skilled in the art within the spirit and scope of the invention.

### REFERENCE LITERATURE

[Reference literature 1] J. Simon et al., “Polarization-Induced Hole Doping in Wide-Band-Gap Uniaxial Semiconductor Heterostructures”, SCIENCE, vol. 327, pp. 60-64, 2010.
[Reference literature 2] R. People and J. C. Bean, “Calculation of critical layer thickness versus lattice mismatch for GexSi1-x/Si strained layer heterostructures”, Applied Physics Letters, vol. 47, no. 3, pp. 322-324, 1985.

### REFERENCE SIGNS LIST

101 Substrate
102 Buffer layer
103 Base layer
104 Channel layer
105 Source electrode
106 Drain electrode
107 Gate electrode

1.-8. (canceled)

9. A semiconductor apparatus comprising:
a buffer layer on a substrate, the buffer layer comprising a nitride semiconductor including Al;
a base layer on the buffer layer, the base layer comprising AlₓGa₁₋ₓN(0<x≤1);
a channel layer on the base layer, the channel layer comprising Al_{y}Ga_{1-y}N(0<y≤1);
a source electrode and a drain electrode on the channel layer; and
a gate electrode on the channel layer between the source electrode and the drain electrode;
wherein the composition x of Al in the base layer decreases in accordance with an increasing approach of the composition x to the channel layer in a thickness direction;
wherein the composition y of Al in the channel layer decreases in accordance with an increasing approach of the composition y to the base layer in the thickness direction; and
wherein both composition ratios of Al of the base layer and the channel layer are equal at an interface between the base layer and the channel layer.

10. The semiconductor apparatus according to claim 9, wherein:
the base layer comprises AlₓGa₁₋ₓN(0.7<x≤1); and
the channel layer comprises Al_{y}Ga_{1-y}N(0.7<y≤1).

11. The semiconductor apparatus according to claim 9, further comprising a barrier layer on the channel layer, the barrier layer comprising a nitride semiconductor including Al.

12. The semiconductor apparatus according to claim 11, wherein the gate electrode is on the barrier layer.

13. The semiconductor apparatus according to claim 12, further comprising a recess in the channel layer, wherein the gate electrode is in the recess.

14. The semiconductor apparatus according to claim 9, further comprising:
a first contact layer on the channel layer, the first contact layer comprising AlGaN; and
a second contact layer on the channel layer, the second contact layer comprising AlGaN.

15. The semiconductor apparatus according to claim 14, wherein:
the source electrode is on the first contact layer;
the drain electrode is on the second contact layer; and
the compositions of Al in the first contact layer and the second contact layer decrease in accordance with an increasing approach of the compositions to an upper layer in the thickness direction.

16. A method for producing a semiconductor apparatus, the method comprising:
forming a buffer layer comprising AlN on a substrate;
forming a base layer comprising AlₓGa₁₋ₓN(0<x≤1) on the buffer layer;
forming a channel layer comprising Al_{y}Ga_{1-y}N(0<y≤1) on the base layer;
forming a source electrode and a drain electrode on the channel layer; and
forming a gate electrode on the channel layer between the source electrode and the drain electrode;
wherein the composition x of Al in the base layer decreases in accordance with an increasing approach of the composition x to the channel layer in a thickness direction;
wherein the composition y of Al in the channel layer decreases in accordance with an increasing approach of the composition y to the base layer in the thickness direction; and
wherein both composition ratios of Al in the base layer and the channel layer are equal at an interface between the base layer and the channel layer.

17. The method according to claim 16, wherein:
the base layer comprises AlₓGa₁₋ₓN(0.7<x≤1); and
the channel layer comprises Al_{y}Ga_{1-y}N(0.7<y≤1).

18. The method according to claim 16, further comprising forming a barrier layer comprising AlN on the channel layer, wherein the gate electrode is formed on the barrier layer.

19. The method according to claim 18, wherein the barrier layer comprises a nitride semiconductor including Al.

20. The method according to claim 19, further comprising forming a recess in the channel layer, wherein forming the gate electrode comprises forming the gate electrode in the recess.

21. The method according to claim 16, further comprising:
forming a first contact layer on the channel layer, the first contact layer comprising AlGaN; and
forming a second contact layer on the channel layer, the second contact layer comprising AlGaN.

22. The method according to claim 21, wherein:
the source electrode is formed on the first contact layer;
the drain electrode is formed on the second contact layer; and
the compositions of Al in the first contact layer and the second contact layer decrease in accordance with an increasing approach of the compositions to an upper layer in the thickness direction.
